(19) United States
(12) Patent Application Publication
(10) Pub. No.: US 2024/0088043 A1
(43) Pub. Date: Mar. 14, 2024

(54) SEMICONDUCTOR DEVICE AND METHOD FOR FABRICATING THE SAME

(71) Applicant: MACRONIX INTERNATIONAL CO., LTD., Hsinchu (TW)

(72) Inventor: Ting-Feng LIAO, Hsin-chu (TW)

(21) Appl. No.: 17/930,450

(22) Filed: Sep. 8, 2022

(51) Int. Cl. H01L 23/535; H01L 27/1157; H01L 27/11582

(52) U.S. Cl. CPC H01L 23/535; H01L 27/1157; H01L 27/11582

(57) ABSTRACT

A semiconductor device includes a ground layer including a lower semiconductor material layer, a refilled semiconductor material layer disposed on the lower semiconductor material layer, and an upper conductive layer disposed on the refilled semiconductor material layer; a stacked structure disposed on the ground layer, including insulating layers and conductive layers alternately stacked along a first direction; and a conductive pillar penetrating the stacked structure and extending into the ground layer. The conductive pillar includes a bottom body portion corresponding to the ground layer, a middle body portion corresponding to middle and bottom portions of the stacked structure, and a plug. In a second direction, a first dimension in a portion of the bottom body portion overlapping the upper conductive layer is greater than a second dimension in a portion of the middle body portion overlapping a bottommost insulating layer of the stacked structure.

### BACKGROUND OF THE INVENTION

### Field of the Invention

The present invention relates to a semiconductor device and a method for fabricating the same, and more particularly to a three-dimensional semiconductor device and a method for fabricating the same.

### Description of the Related Art

In recent years, the size of semiconductor devices has to be gradually reduced. As the size of the semiconductor devices shrinks, manufacturing errors are more likely to occur in the process of manufacturing the semiconductor device. The manufacturing errors may affect the electrical characteristics of the semiconductor device, and even lead to chip failure in severe cases. Therefore, there is still an urgent need to improve the manufacturing errors of miniaturized semiconductor devices.

### SUMMARY OF THE INVENTION

The present invention relates to a semiconductor device and a method for fabricating the semiconductor device. Since the method for fabricating the semiconductor device of the present application includes forming a conductive material layer, the conductive material layer can be used as an etching stop layer, and there is no problem of over-etching.

According to an embodiment of the present invention, a semiconductor device is provided. The semiconductor device includes a ground layer, a stacked structure and at least one conductive pillar. The ground layer includes a lower semiconductor material layer, a refilled semiconductor material layer disposed on the lower semiconductor material layer, and an upper conductive layer disposed on the refilled semiconductor material layer. The stacked structure is disposed on the ground layer, and the stacked structure includes a plurality of insulating layers and a plurality of conductive layers alternately stacked along a first direction. The conductive pillar penetrates the stacked structure along the first direction and extends into the ground layer, wherein the conductive pillar includes a bottom body portion, a middle body portion, and a plug connected to each other, wherein the bottom body portion corresponds to the ground layer, and the middle body portion corresponds to middle and bottom portions of the stacked structure. In a second direction different from the first direction, a portion of the bottom body portion overlapping the upper conductive layer has a first dimension, and a portion of the middle body portion overlapping a bottommost insulating layer of the stacked structure has a second dimension, the first dimension is greater than the second dimension.

According to another embodiment of the present invention, a semiconductor device is provided. The semiconductor device includes a ground layer and a stacked structure. The ground layer includes a lower semiconductor material layer, a refilled semiconductor material layer disposed on the lower semiconductor material layer, and an upper conductive layer disposed on the refilled semiconductor material layer. The stacked structure is disposed on the ground layer, and the stacked structure includes a plurality of insulating layers and a plurality of conductive layers alternately stacked along a first direction. The upper conductive layer includes a conductive material which includes a metal material.

According to a further embodiment of the present invention, a method for fabricating a semiconductor device is provided. The method includes the following steps. A multilayer structure is provided on a circuit board. The multilayer structure includes a lower semiconductor material layer, a first interlayer insulating layer, a middle semiconductor material layer, a second interlayer insulating layer and an upper conductive layer sequentially stacked on the circuit board along a first direction. A conductive material layer is formed in the upper conductive layer, wherein the conductive material layer includes a metal material. A laminated body is formed on the upper conductive layer, and the laminated body includes a plurality of insulating layers and a plurality of sacrificial layers stacked alternately. At least one trench is formed in the laminated body, wherein the trench extends along the first direction, penetrates the laminated body and stops at the conductive material layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1 to 16 are cross-sectional views illustrating a method for fabricating a semiconductor device according to an embodiment of the present invention.

FIGS. 17 to 32 are cross-sectional views illustrating a method for fabricating a semiconductor device according to another embodiment of the present invention.

### DETAILED DESCRIPTION OF THE INVENTION

The following are related embodiments, which are combined with the drawings to describe in detail the semiconductor structure and a method for fabricating the same provided by the present invention. However, the present invention is not limited thereto. The descriptions in the embodiments, such as the detailed structure, the steps of the fabricating method, and the application of materials, etc., are only for the purpose of illustration, and the scope of protection of the present invention is not limited to the above-mentioned aspects.

At the same time, it should be noted that the present invention does not show all possible embodiments. Those skilled in the relevant art can make changes and modifications to the structures and manufacturing methods of the embodiments without departing from the spirit and scope of the present invention, so as to meet the needs of practical applications. Therefore, other implementation aspects not proposed in the present invention may also be applicable. Furthermore, the drawings are simplified for the purpose of clearly explaining the contents of the embodiments, and the dimension ratios in the drawings are not drawn according to the actual product scale. The same or similar reference numerals are used in the drawings to represent the same or similar elements. It is contemplated that the elements and features of one embodiment can be beneficially incorporated in another embodiment without further recitation.

Furthermore, the ordinal numbers such as “first”, “second”, “third” and other terms used in the description and the claims of the present application are for modifying the elements, and they do not imply and represent that the elements have any one of the previous ordinal numbers; they do not represent the order of a certain element and another element, or the order of the fabricating method. The use of these ordinal numbers is only used to enable an element with a certain name to be clearly distinguished from another element having the same name.

The embodiments of the present invention could be implemented in many different 3D stacked semiconductor structures in the applications. For example, the embodiment could be applied to, but not limited to, the 3D vertical-channel (VC) NAND memory devices or other types of memory device.

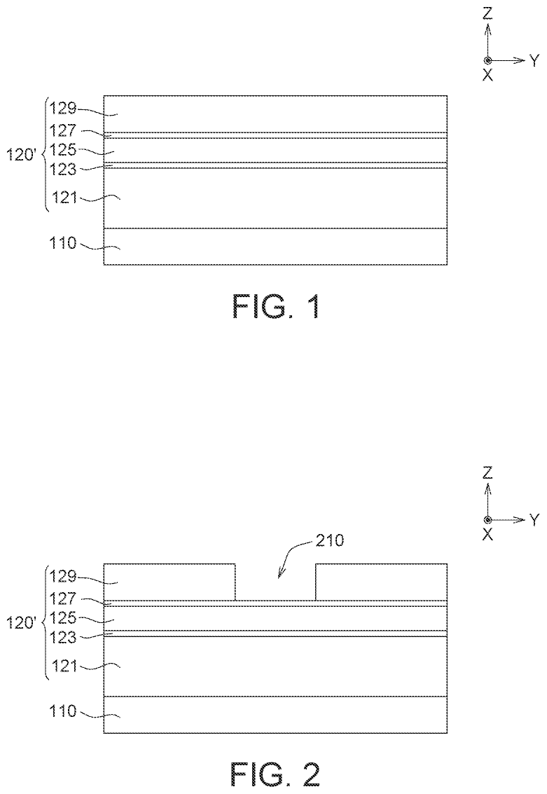

FIGS. 1 to 16 are cross-sectional views illustrating a method for fabricating a semiconductor device 10 according to an embodiment of the present invention.

Please refer to FIG. 1. A multilayer structure 120′ is provided on a circuit board 110. The multilayer structure 120′ includes a lower semiconductor material layer 121, a first interlayer insulating layer 123, a middle semiconductor material layer 125, an interlayer insulating layer 127 and an upper conductive layer 129 sequentially stacked on the circuit board 110 along the Z direction (e.g., first direction) from the bottom to top.

In one embodiment, the lower semiconductor material layer 121, the middle semiconductor material layer 125, and the upper conductive layer 129 may include doped or undoped semiconductor materials, such as doped or undoped polysilicon. The first interlayer insulating layer 123 and the second interlayer insulating layer 127 may include insulating materials, and the insulating materials include oxides, such as silicon oxide. In one embodiment, the multilayer structure 120′ may be formed on the circuit board 110 by sequentially depositing the lower semiconductor material layer 121, the first interlayer insulating layer 123, the middle semiconductor material layer 125, the second interlayer insulating layer 127 and the upper conductive layer 129, for example, by a chemical vapor deposition (CVD).

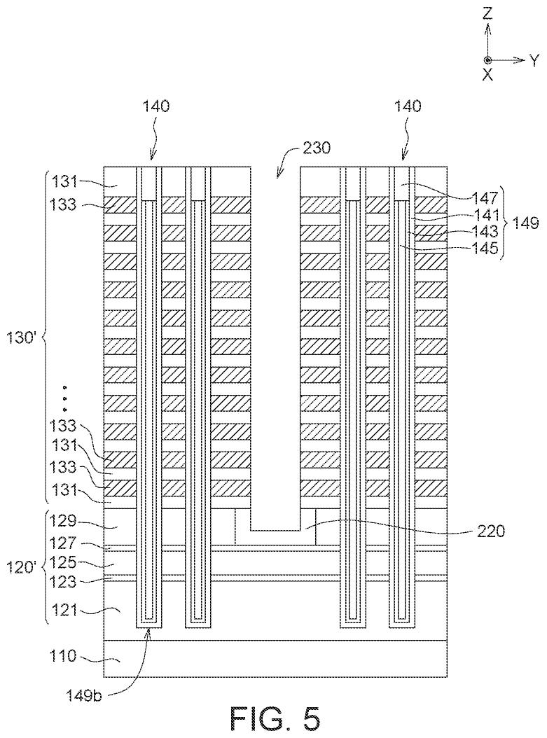

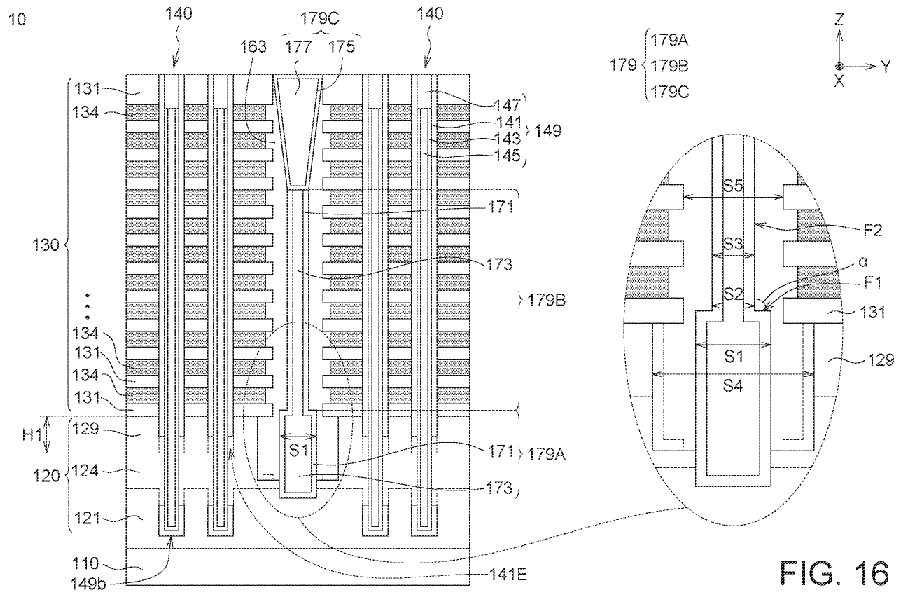

Please refer to FIG. 2. After forming the multilayer structure 120′, a portion of the upper conductive layer 129 is removed to form a groove 210 exposing the second interlayer insulating layer 127. For example, a portion of the upper conductive layer 129 can be etched at a predetermined position by a lithography process. The predetermined position overlaps the position where the trench 230 (shown in FIG. 5) is to be formed in the Z direction, and a width of the groove 210 in the Y direction (e.g., second direction) may be greater than a width of a trench 230 (shown in FIG. 5) in the Y direction, where the trench 230 (shown in FIG. 5) is used to form a conductive pillar 179 (shown in FIG. 16). The groove 210 may extend along the X direction (e.g., third direction).

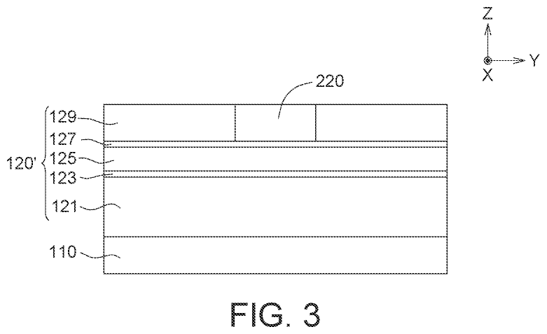

Please refer to FIG. 3. A conductive material is filled in the groove 210 to form a conductive material layer 220 in the groove 210. In other words, the conductive material layer 220 may be formed in the upper conductive layer 129. According to one embodiment, the conductive material may be deposited in the groove 210, and then a chemical-mechanical planarization (CMP) may be performed, so that a top surface of the conductive material layer 220 and a top surface of the upper conductive layer 129 may be coplanar. In some embodiments, the material of conductive material layer 220 includes a metal material, such as tungsten (W).

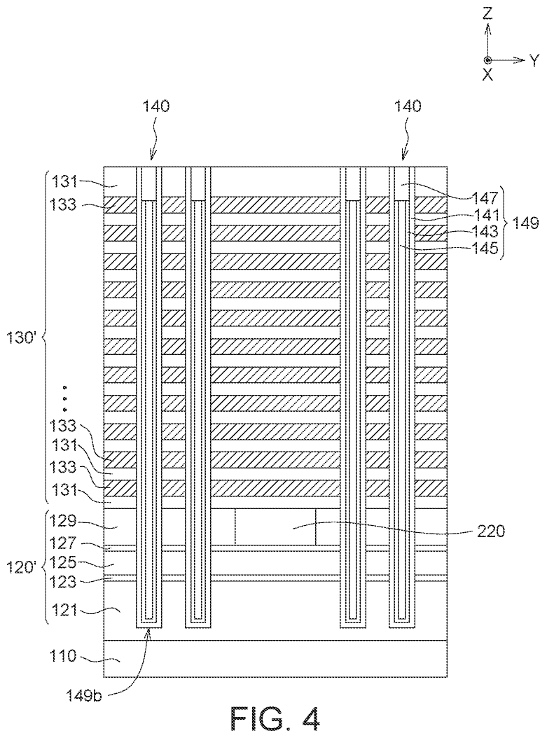

Please refer to FIG. 4. A laminated body 130′ is formed on the upper conductive layer 129 and the conductive material layer 220, and then a plurality of channel structures 149 are formed penetrating through the laminated body 130′ and a portion of the multilayer structure 120′ along the Z direction. The laminated body 130′ includes a plurality of insulating layers 131 and sacrificial layers 133 stacked alternately, wherein the bottommost layer and the topmost layer of the laminated body 130′ may be the insulating layers 131. Lower channel ends 149b of the channel structures 149 may be located in the lower semiconductor material layer 121. Each of the channel structures 149 may include a memory film 141, a channel film 143, an insulating pillar 145 and a pad 147.

The memory film 141 may include a multilayer structure known in the field of memory technology, such as an ONO (oxide-nitride-oxide) structure, ONONO (oxide-nitride-oxide-nitride-oxide) structure, ONONONO (oxide-nitride-oxide-nitride-oxide-nitride-oxide) structure, SONOS (silicon-silicon oxide-silicon nitride-silicon oxide-silicon) structure, BE-SONOS (bandgap engineered silicon-silicon oxide-silicon nitride-silicon oxide-silicon) structure, TANOS (tantalum nitride-aluminium oxide-silicon nitride-silicon oxide-silicon) structure, MA BE-SONOS (metal-high dielectric constant material bandgap engineered silicon-silicon oxide-silicon nitride-silicon oxide-silicon) structure and a combination thereof.

The channel film 143 may comprise a doped or undoped semiconductor material, such as doped polysilicon or undoped polysilicon. The insulating pillars 145 may include a dielectric material including an oxide (e.g., silicon oxide). The pads 147 may include doped or undoped semiconductor material, such as doped polysilicon or undoped polysilicon.

According to some embodiments, a plurality of insulating layers 131 and a plurality of sacrificial layers 133 may be alternately deposited on the upper conductive layer 129 and the conductive material layer 220 to form the laminated body 130′. Thereafter, a plurality of vertical openings 140 are formed in the laminated body 130′ through a patterning process. For example, the laminated body 130′ may be pattered by a photolithography process. The vertical openings 140 can penetrate through the laminated body 130′, the upper conductive layer 129, the second interlayer insulating layer 127, the middle semiconductor material layer 125 and the first interlayer insulating layer 123 along the Z direction, and stop at the lower semiconductor material layer 121. That is, the lower semiconductor material layer 121 is exposed. Next, a memory film 141, a channel film 143, an insulating pillar 145 and a pad 147 are sequentially deposited in each of the vertical openings 140 to form the channel structures 149. The insulating layer 131 may include oxide, such as silicon oxide. The sacrificial layer 133 may include nitride, such as silicon nitride.

Please refer to FIG. 5. A patterning process is performed to the laminated body 130′ to form at least one trench 230 in the laminated body 130′. For example, the laminated body 130′ may be patterned by a lithography process. The trench 230 may extend downward along the Z direction, penetrating through the laminated body 130′ and stop at the conductive material layer 220. The conductive material layer 220 may serve as an etch stop layer. The laminated body 130′ and the conductive material layer 220 are exposed by the trench 230 (the laminated body 130′ and the conductive material layer 220 also serve as sidewalls of the trench 230). In one embodiment, the trench 230 may be formed by an etching process (e.g., deep etching). Since the etching process has a high selectivity between the material of the laminated body 130′ and the material of the conductive material layer 220, it can be ensured that the etching process stops at the conductive material layer 220, and there is no problem of over-etching.

It should be understood that since the trench 230 has a high aspect ratio, widths of the trench 230 in the Y direction decreases from top to bottom, although this pattern is not shown in the figures of the present application.

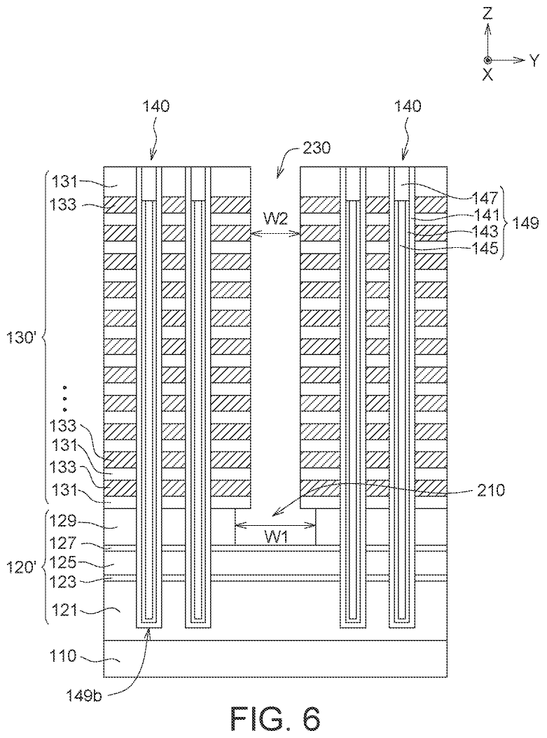

Please refer to FIG. 6. The conductive material layer 220 is removed and the upper conductive layer 129 and the second interlayer insulating layer 127 are exposed (i.e., the groove 210 is exposed again), so that the trench 230 and the groove 210 communicate with each other. As shown in FIG. 6, the trench 230 and the groove 210 overlap each other in the Z direction, and a width W1 of the groove 210 in the Y direction (e.g., the second direction) may be greater than a width W2 of the trench 230 in the Y direction, a depth of the groove 210 in the Z direction (e.g., the first direction) is smaller than a depth of the trench 230 in the Z direction.

In a comparative example, the trench exposing the upper conductive layer and the second interlayer insulating layer can be formed by two etching steps, without forming the groove and the conductive material filled in the groove before forming the trench. Compared with the comparative example without the conductive material layer as the etch stop layer, since the embodiment of the present invention forms the conductive material layer 220 as the etch stop layer, the etching process for forming the trench 230 can be safely stopped at the conductive material layer 220, that is, the depth of the trench 230 can be precisely controlled, and there is no problem of over-etching, so in the subsequent process for forming a conductive pillar (such as a common source line), it is not easy to be over-etched to form a seam as the conductive material cannot fill up the trench for forming the conductive pillar, which can prevent the conductive material from passing through the seam to cause short circuits between the conductive pillar and the channel structure. Therefore, the formed semiconductor device 10 can have better electrical properties.

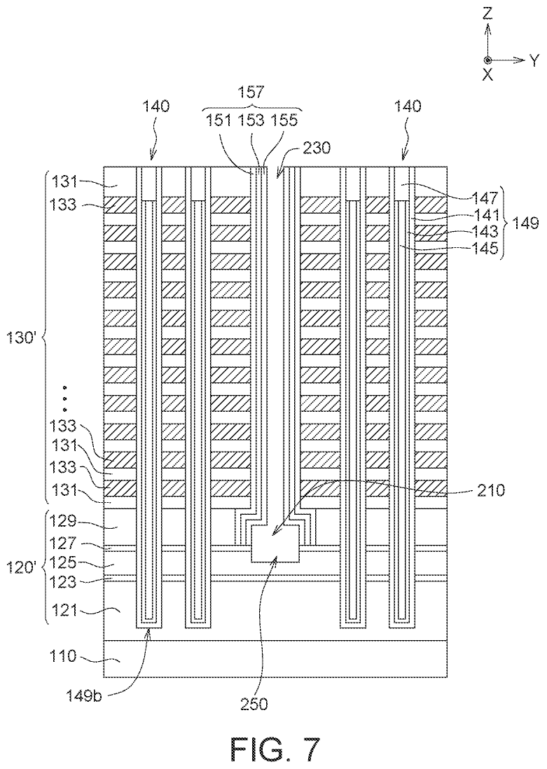

Please refer to FIG. 7. A spacer structure 157 is formed on the sidewall of the trench 230 and the sidewall of the groove 210 shown in FIG. 6. The spacer structure 157 may include an insulating film 151, an insulating film 153 and an insulating film 155. For example, the insulating film 151 can be formed on the upper surface of the laminated body 130′ and lined in the trench 230 and the groove 210 by a deposition process, and then a portion of the insulating film 151 disposed on the bottom of the groove 210 can be removed by an etching step. Next, the insulating film 153 can be formed on the insulating film 151 by a deposition process, and then a portion of the insulating film 153 disposed on the bottom of the groove 210 can be removed by an etching step. After that, the insulating film 155 can be formed on the insulating film 153 by a deposition process, and then a portion of the insulating film 155 disposed on the bottom of the groove 210 can be removed by an etching step. At this time, a portion of the second interlayer insulating layer 127 may be exposed by the bottom of the groove 210. Next, a chemical mechanical planarization may be performed to remove the insulating film 151, the insulating film 153, and the insulating film 155 disposed on the upper surface of the laminated body 130′. The insulating film 151 may include an insulating material including a nitride, such as silicon nitride. The insulating film 153 may include an insulating material including an oxide, such as silicon oxide. The insulating film 155 may include an insulating material including a nitride, such as silicon nitride.

As shown in FIG. 7, an etching step is performed after the spacer structure 157 is formed. The etching step stops at the middle semiconductor material layer 125 to form a notch 250 penetrating through the second interlayer insulating layer 127 and exposing the middle semiconductor material layer 125. A width of the notch 250 in the Y direction is smaller than the width of the trench 230 in the Y direction and the width of the groove 210 in the Y direction. The trench 230, the groove 210 and the notch 250 communicate with each other.

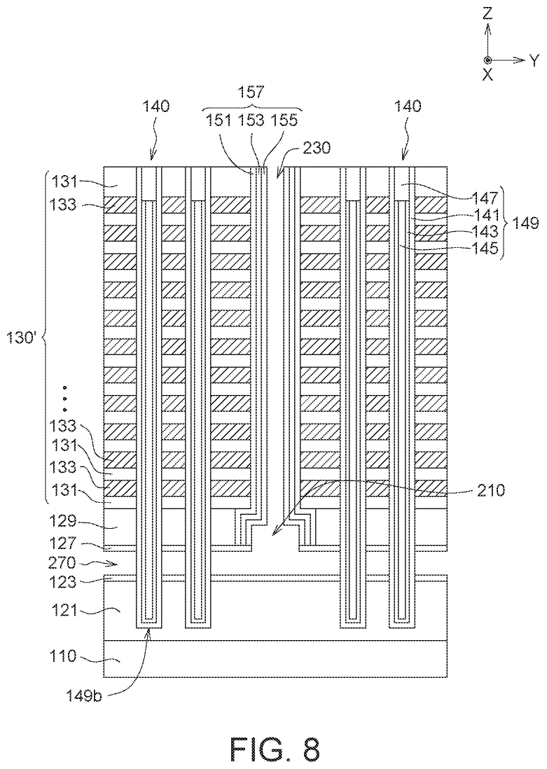

Please refer to FIG. 8. An etching step may be performed to remove the middle semiconductor material layer 125 through the trench 230, the groove 210 and the notch 250 to form the slit 270. The slit 270 is disposed between the first interlayer insulating layer 123 and the second interlayer insulating layer 127. This etching step can substantially remove the middle semiconductor material layer 125 without removing the lower semiconductor material layer 121 disposed below the first interlayer insulating layer 123 and the upper conductive layer 129 disposed above the second interlayer insulating layer 127. Portions of the sidewalls of the channel structures 149 are exposed by the slit 270. Specifically, portions of the sidewalls of the memory films 141 of the channel structures 149 are exposed by the slit 270.

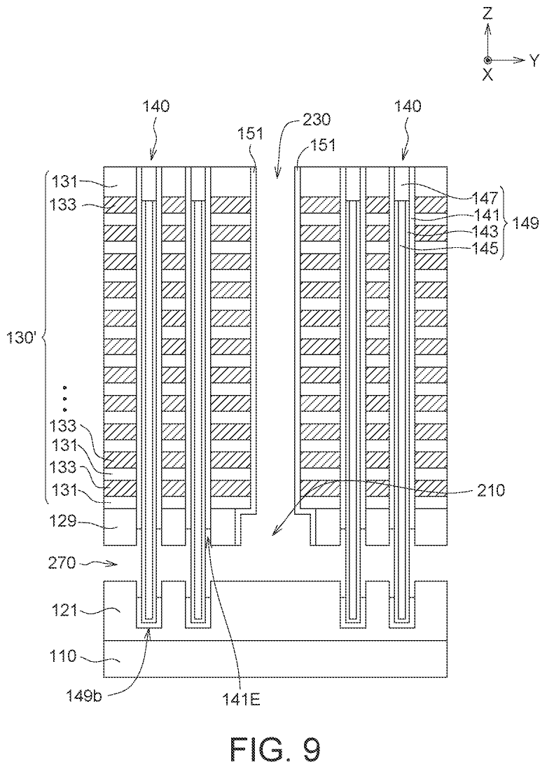

Please refer to FIG. 9. One or more etching steps may be performed to remove a portion of the memory films 141 of the channel structures 149, the first interlayer insulating layer 123, the second interlayer insulating layer 127, and portions of the insulating films (i.e., insulating film 153 and insulating film 155). In one embodiment, the insulating film 151 on the sidewall of the trench 230 and the sidewall of the groove 210 may be retained. Each of the memory films 141 removed by the etching step includes a top removal portion 141E connected to a bottom surface of the memory film 141 corresponding to the upper conductive layer 129.

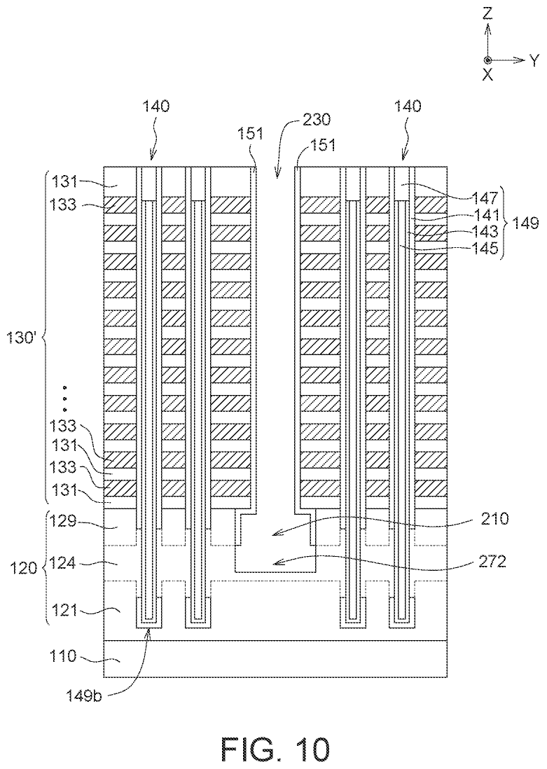

Please refer to FIG. 10. A refilled semiconductor material layer 124 may be formed between the lower semiconductor material layer 121 and the upper conductive layer 129 by a deposition process. For example, a semiconductor material may be deposited in the slit 270 by a deposition process, and then a portion of the refilled semiconductor material layer 124 may be removed by an etching back process to form an extending opening 272, and the refilled semiconductor material layer 124 is exposed by the extending opening 272. The trench 230, the groove 210 and the extending opening 272 may communicate with each other. In one embodiment, the refilled semiconductor material layer 124 may connect or contact the memory film 141, the channel film 143, the lower semiconductor material layer 121 and the upper conductive layer 129. In one embodiment, the refilled semiconductor material layer 124 may include doped or undoped semiconductor material, such as doped or undoped polysilicon. The lower semiconductor material layer 121, the refilled semiconductor material layer 124 and the upper conductive layer 129 may form the ground layer 120. The ground layer 120 may include doped or undoped semiconductor material, such as doped or undoped polysilicon. The doping concentrations of the lower semiconductor material layer 121, the refilled semiconductor material layer 124 and the upper conductive layer 129 may be different from each other, but the present invention is not limited thereto.

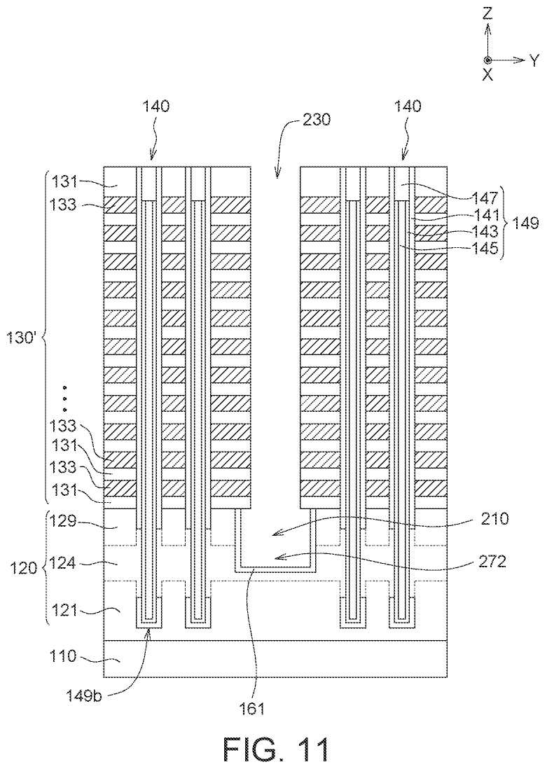

Please refer to FIG. 11. An etching step may be performed to remove the remaining portion of the insulating film 151, and to form a protective layer 161 on the sidewalls of the notch 210 and the extending opening 272, and on the bottom of the extending opening 272. The protective layer 161 may cover the ground layer 120 exposed by the groove 210 and the extending opening 272. In one embodiment, the protective layer 161 may include an insulating material, and the insulating material includes an oxide, such as silicon oxide. For example, the surface of the ground layer 120 exposed by the groove 210 and the extending opening 272 can be oxidized to be the protective layer 161 by an oxidation process.

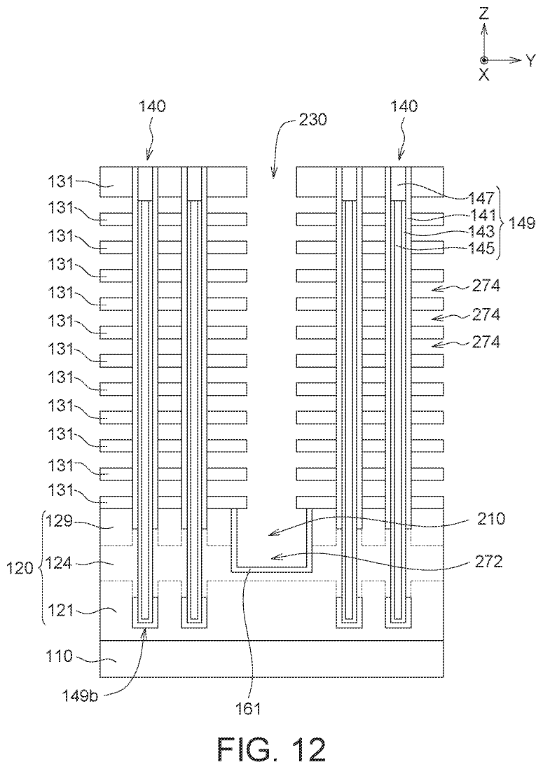

Please refer to FIG. 12. An etching step may be performed through the trench 230 to remove the sacrificial layers 133 of the laminated body 130′, and plurality of spaces 274 between the insulating layers 131 are formed. In this etching step, the protective layer 161 may protect the ground layer 120 to prevent the ground layer 120 from being removed in the etching step. In one embodiment, the etching step may include wet etching, such as using hot phosphoric acid (H₃PO₄) or other suitable chemicals.

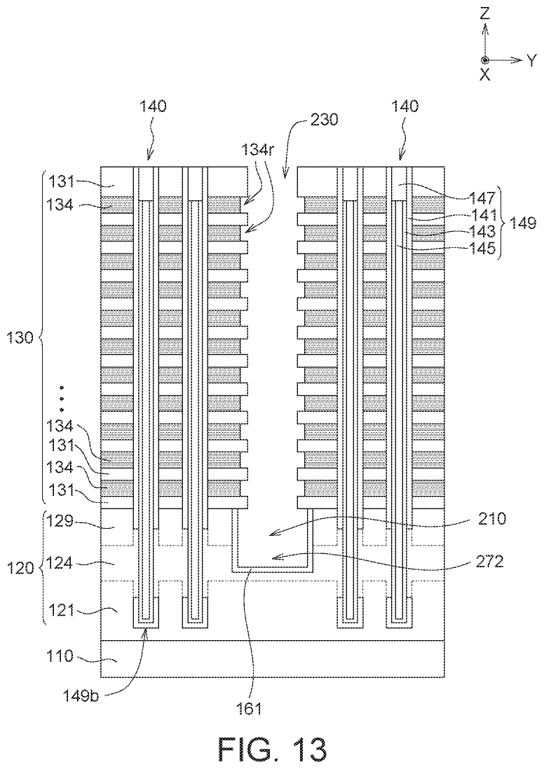

Please refer to FIG. 13. The spaces 274 are filled with a conductive material to form a plurality of conductive layers 134 disposed between the insulating layers 131. For example, a conductive material is deposited in the spaces 274, and then an etching back process is performed to remove a portion of each conductive layer 134 adjacent to the trench 230 to form recesses 134r disposed between the insulating layers 131 and the conductive layers 134. The trench 230 and the recesses 134r communicate with each other. The alternately stacked insulating layers 131 and the conductive layers 134 may jointly form a stacked structure 130.

In one embodiment, the steps included in FIGS. 12 to 13 may be understood as a gate replacement process. In one embodiment, the conductive layer 134 may include a conductive material, such as tungsten (W).

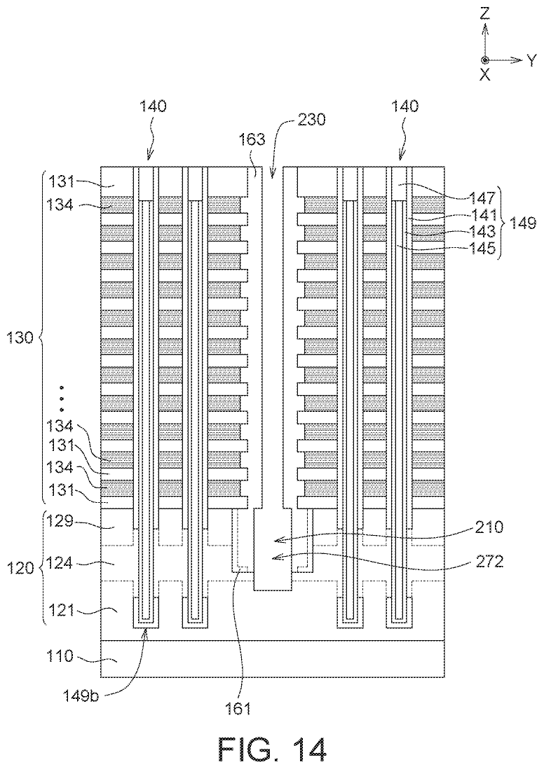

Please refer to FIG. 14. An isolation material layer 163 may be formed by a deposition process to be filled in the recesses 134r and lined in the trench 230, the groove 210 and the extending opening 272. After that, an etching step can be performed to remove a portion of the isolation material layer 163 and the protective layer 161 at the bottom of the extending opening 272, and the ground layer 120 is exposed. Thereby, the isolation material layer 163 covering the sidewalls of the trench 230, the groove 210 and the extending opening 272 can be formed. That is, the isolation material layer 163 may cover the exposed sidewalls of the conductive layers 131 and the insulating layers 134 of the stacked structure 130 and cover the protective layer 161. In one embodiment, the isolation material layer 163 may include an oxide, such as a low temperature oxide (LTO).

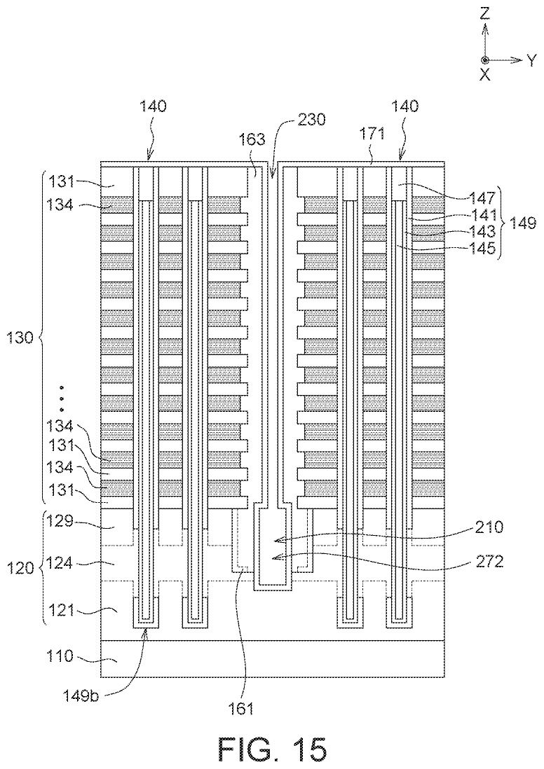

After the isolation material layer 163 is formed, a conductive pillar 179 is formed between the isolation material layer 163 and the ground layer 120, as shown in FIGS. 15-16. FIGS. 15-16 illustrate a method for fabricating the conductive pillar 179 according to an embodiment of the present invention, but the present invention is not limited thereto.

Please refer to FIG. 15. After the isolation material layer 163 is formed, a body barrier layer 171 may be lined on the stacked structure 130 and in the trench 230, the groove 210 and the extending opening 272 by a deposition process. The body barrier layer 171 may directly contact the ground layer 120.

Please refer to FIG. 16. The excess portion of the body barrier layer 171 disposed on the stacked structure 130 can be removed, and the lower conductive layer 173 can be formed in the trench 230, the groove 210 and the extending opening 272. After that, portions of the isolation material layer 163, the body barrier layer 171 and the lower conductive layer 173 disposed in an upper portion of the trench 230 are removed to form an upper opening (not shown), and a plug 179C including an upper barrier layer 175 and an upper conductor 177 is formed in the upper opening. The body barrier layer 171 and the lower conductive layer 173 disposed under the plug 179C form a middle body portion 179B and a bottom body portion 179A. That is, the middle body portion 179B and the bottom body portion 179A include the body barrier layer 171 and the lower conductive layer 173. In this way, the conductive pillar 179 including the bottom body portion 179A, the middle body portion 179B, and the plug 179C is formed.

The body barrier layer 171 and the upper barrier layer 175 may prevent foreign atoms from entering the device by diffusion. In one embodiment, the material of the body barrier layer 171 and the upper barrier layer 175 can be independently titanium (Ti), titanium nitride (TiN), tantalum (Ta), tantalum nitride (TaN) or other suitable materials.

In the present embodiment, the material of the upper conductor 177 is different from the material of the lower conductive layer 173, the material of the upper conductor 177 may include a metal material, such as tungsten; the material of the lower conductive layer 173 may include doped or undoped semiconductor materials, such as doped or undoped polysilicon. In another embodiment, both the upper conductor 177 and the lower conductive layer 173 may include metal materials, such as tungsten. In other embodiments, both the upper conductor 177 and the lower conductive layer 173 may include doped or undoped semiconductor material, such as doped or undoped polysilicon, and there is no upper barrier layer 175 and body barrier layer 171 disposed between the upper conductor 177 and the isolation material layer 163, and between the lower conductive layer 173 and the isolation material layer 163, that is, the upper conductor 177 and the lower conductive layer 173 can directly contact the isolation material layer 163.

As shown in FIG. 16, the semiconductor device 10 includes a circuit board 110, a ground layer 120, a stacked structure 130, a plurality of channel structures 149, an isolation material layer 163 and at least one conductive pillar 179. The ground layer 120 is disposed on the circuit board 110, and the stacked structure 130 is disposed on the ground layer 120.

The stacked structure 130 includes a plurality of insulating layers 131 and a plurality of conductive layers 134 alternately stacked on the ground layer 120 along the Z direction (e.g., the first direction). The channel structures 149 penetrate through the stacked structure 130 and extend into the ground layer 120 along the Z direction (e.g., the first direction). More specifically, the ground layer 120 includes lower semiconductors material layer 121, the refilled semiconductor material layer 124 and the upper conductive layer 129 sequentially stacked on the circuit board 110 along the Z direction. The lower channel ends 149b of the channel structures 149 may extend into the lower semiconductor material layer 121.

Each of the channel structures 149 may include a memory film 141, a channel film 143, an insulating pillar 145 and a pad 147, the channel film 143 surrounds the insulating pillar 145, the memory film 141 surrounds the channel film 143, and the pad 147 is disposed on the channel film 143 and the insulating pillar 145, and the materials of each of elements are as described above. A portion of the channel film 143 is exposed by the memory film 141, so that the ground layer 120 directly contacts the channel film 143 and the memory film 141.

The conductive pillar 179 penetrates through the stacked structure 130 and extends into the ground layer 120 along the Z direction (e.g., the first direction). The conductive pillar 179 includes a bottom body portion 179A, a middle body portion 179B, and a plug 179C connected to each other, and the middle body portion 179B is disposed between the bottom body portion 179A and the plug 179C. That is, the middle body portion 179B is disposed on the bottom body portion 179A, and the plug 179C is disposed on the middle body portion 179B.

The bottom body portion 179A corresponds to the ground layer 120, for example, the bottom body portion 179A extends into the ground layer 120, and overlaps the ground layer 120 in the Y direction (e.g., the second direction). The middle body portion 179B corresponds to the middle and bottom portions of the stacked structure 130; the plug 179C corresponds to the top portion of the stacked structure 130. For example, in the Y direction, the middle body portion 179B overlaps the middle and bottom portions of the stacked structure 130, and the plug 179C overlaps the top portion of the stacked structure 130. The conductive pillar 179 is, for example, used as a common source line (CSL), and is in electrical contact with the ground layer 120.

According to an embodiment, outer sidewalls of the conductive pillar 179 have a kink profile at a portion adjacent to the bottommost insulating layer 131 of the stacked structure 130, that is, the dimension in the Y direction varies. For example, the outer sidewalls of the conductive pillar 179 has a first surface F1 at the portion corresponding to the bottom body portion 179A and adjacent to the kink profile, and has a second surface F2 at the portion corresponding to the middle body portion 179B and adjacent to the kink profile. An angle α disposed between the first surface F1 and the second surface F2 may approach 90 degrees, for example, 70 to 90 degrees. Since the trench 230 has a high aspect ratio, a width of the middle body portion 179B (overlapping the stacked structure 130 in the Y direction) formed in the trench 230 in the Y direction decreases from top to bottom. Further, in the Y direction, a portion of the bottom body portion 179A that overlaps the upper conductive layer 129 of the ground layer 120 has a first dimension S1, and a portion of the middle body portion 179B that overlaps the bottommost insulating layer 131 of the stacked structure 130 has a second dimension S2, and a portion of the middle body portion 179B that overlaps a portion disposed above the bottommost insulating layer 131 of the stacked structure 130 has a third dimension S3. The first dimension S1 is greater than the second dimension S2 and the third dimension S3, and the third dimension S3 is greater than the second dimension S2, for example, it satisfies the relational expression “S1>S3>S2”. In the ground layer 120, the refilled semiconductor material layer 124 is filled in the top removal portion 141E of the memory film 141. The bottom body portion 179A corresponding to the top removal portion 141E may also have the first dimension S1. In other words, in the Y direction, a portion of the bottom body portion 179A overlapping a top protrusion of the refilled semiconductor material layer 124 (i.e., the top protrusion formed by filling the refilled semiconductor material layer 124 in the top removal portion 141E) may also have the first dimension S1. According to an embodiment, in the Z direction (e.g., the first direction), a height H1 is formed between a bottom surface of the bottommost insulating layer 131 of the stacked structure 130 and a bottom surface of the upper conductive layer 129. The height H1 is greater than 0 nm and less than or equal to 60 nm (0 nm<H1≤60 nm), such as 20 to 60 nm, 25 to 55 nm or other suitable ranges. In some embodiments, a thickness of the lower semiconductor material layer 121 is greater than a thickness of the refilled semiconductor material layer 124 and a thickness of the upper conductive layer 129.

According to an embodiment, the isolation material layer 163 is disposed between the conductive pillar 179 and the stacked structure 130 and between the conductive pillar 179 and the ground layer 120. In the Y direction, a maximum dimension S4 of a portion of the isolation material layer 163 overlapping the upper conductive layer 129 of the ground layer 120 is greater than a maximum dimension S5 of a portion of the isolation material layer 163 overlapping the stacked structure 130 (such as the portion of the isolation material layer 163 disposed between the conductive layers 134).

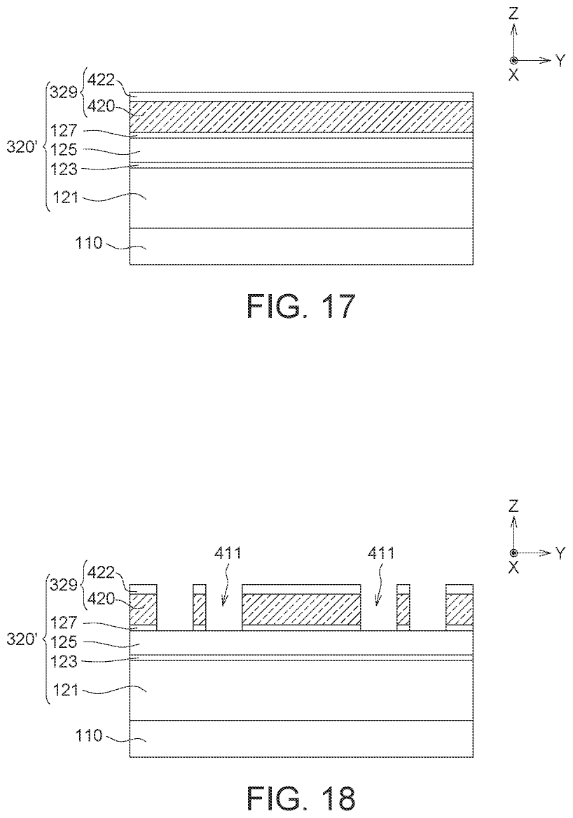

FIGS. 17 to 32 are cross-sectional views illustrating a method for fabricating a semiconductor device 30 according to another embodiment of the present invention.

The main difference between the fabrication method of the semiconductor device 30 and the fabrication method of the semiconductor device 10 is in that the upper conductive layer 129 is replaced with an upper conductive layer 329, which includes a conductive material layer 420. The semiconductor device 30 and a method for fabricating the same are partially similar or identical to the semiconductor device 10 and the method for fabricating the same. Similar or identical elements are marked with similar or identical component symbols, and have similar or identical positions, formation methods, structures, materials or functions, and repeated contents will not be described in detail.

Please refer to FIG. 17. A multilayer structure 320′ is provided on the circuit board 110. The multilayer structure 320′ includes a lower semiconductor material layer 121, a first interlayer insulating layer 123, a middle semiconductor material layer 125, a second interlayer insulating layer 127 and an upper conductive layer 329. The upper conductive layer 329 includes a conductive material layer 420 and an insulating material layer 422. That is, a conductive material layer 420 is formed in the upper conductive layer 329. In some embodiments, the material of the conductive material layer 420 includes a metal material, such as tungsten. The insulating material layer 422 may include an insulating material including an oxide, such as silicon oxide.

In one embodiment, the lower semiconductor material layer 121, the first interlayer insulating layer 123, the middle semiconductor material layer 125, the second interlayer insulating layer 127, the conductive material layer 420, and the insulating material layer 422 may be sequentially deposited to form the multilayer structure 320′ on the circuit board 110 by, for example, chemical vapor deposition (CVD).

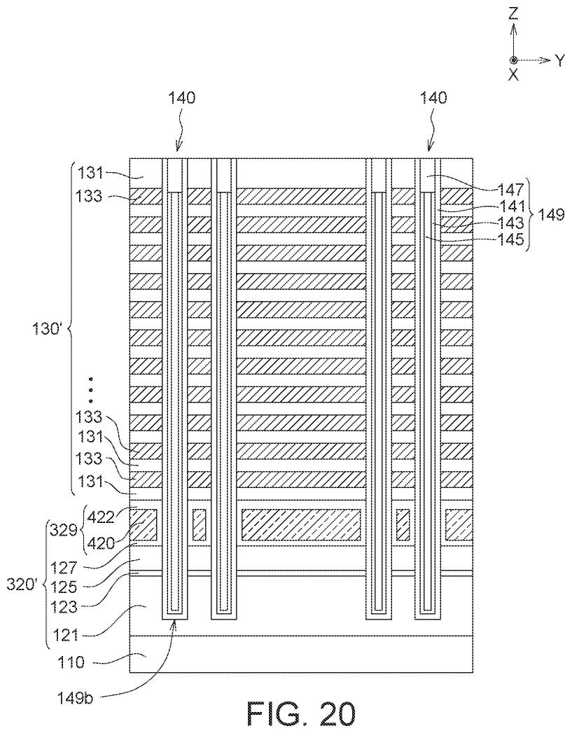

Please refer to FIG. 18. After the multilayer structure 320′ is formed, portions of the upper conductive layer 329 are removed to form holes 411 exposing the middle semiconductor material layer 125. For example, portions of the upper conductive layer 329 may be etched at predetermined positions by a lithography process. The predetermined positions overlap the positions where the channel structures 149 (shown in FIG. 20) are to be formed in the Z direction.

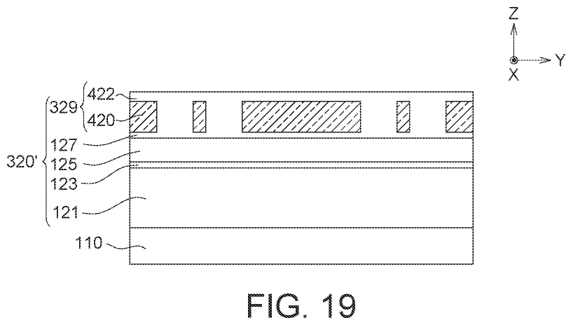

Please refer to FIG. 19. The holes 411 may be filled with an insulating material by a deposition process. Thereafter, a chemical-mechanical planarization (CMP) may be performed.

Please refer to FIG. 20. A laminated body 130′ is formed on the upper conductive layer 329, and then a plurality of channel structures 149 are formed penetrating through the laminated body 130′ and a portion of the multilayer structure 120′ along the Z direction. The laminated body 130′ includes a plurality of insulating layers 131 and sacrificial layers 133 stacked alternately, wherein the bottommost layer and the topmost layer of the laminated body 130′ may be the insulating layers 131. The lower channel ends 149b of the channel structures 149 may be located in the lower semiconductor material layer 121. Each of the channel structures 149 may include a memory film 141, a channel film 143, an insulating pillar 145 and a pad 147.

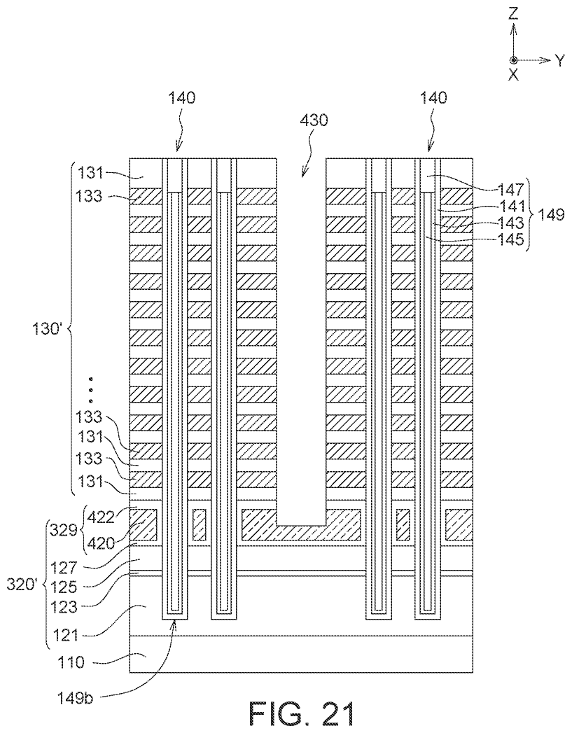

Please refer to FIG. 21. A patterning process is performed on the laminated body 130′ to form at least one trench 430 in the laminated body 130′. For example, the laminated body 130′ may be patterned by a lithography process. The trench 430 may extend downward along the Z direction, penetrating through the laminated body 130′ and stop at the conductive material layer 420. The conductive material layer 420 may serve as an etch stop layer. The laminated body 130′, conductive material layer 420, and insulating material layer 422 are exposed by the trench 430, and the laminated body 130′, conductive material layer 420, and insulating material layer 422 also serve as sidewalls of the trench 430. In one embodiment, the trench 430 may be formed by an etching process (e.g., deep etching). Since the etching process has a high selectivity between the material of the laminated body 130′ and the material of the conductive material layer 420, it can be ensured that the etching process stops at the conductive material layer 420, and there is no problem of over-etching.

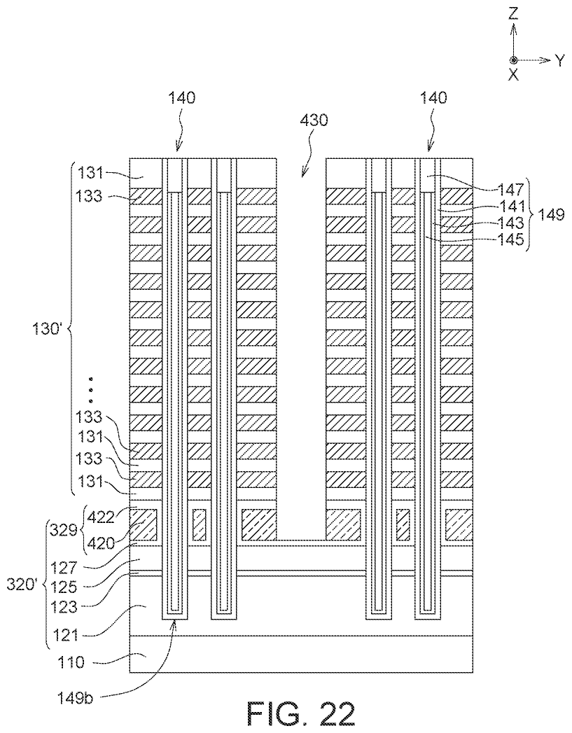

Please refer to FIG. 22. A portion of the conductive material layer 420 may be removed by an etching step and the second interlayer insulating layer 127 may be exposed, so that the depth of the trench 430 may be extended.

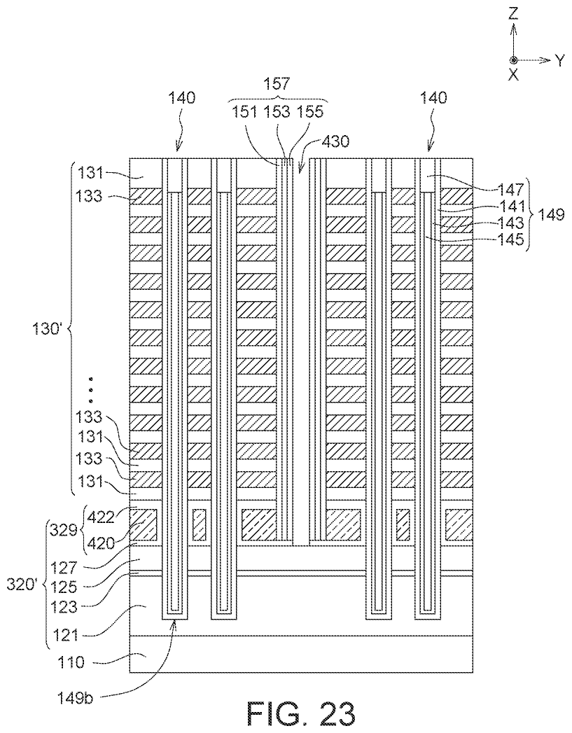

Please refer to FIG. 23. A spacer structure 157 is formed on the sidewall of the trench 430 shown in FIG. 22. The spacer structure 157 may include an insulating film 151, an insulating film 153 and an insulating film 155. An etching step is performed after the spacer structure 157 is formed. The etching step stops at the middle semiconductor material layer 125 and the middle semiconductor material layer 125 is exposed.

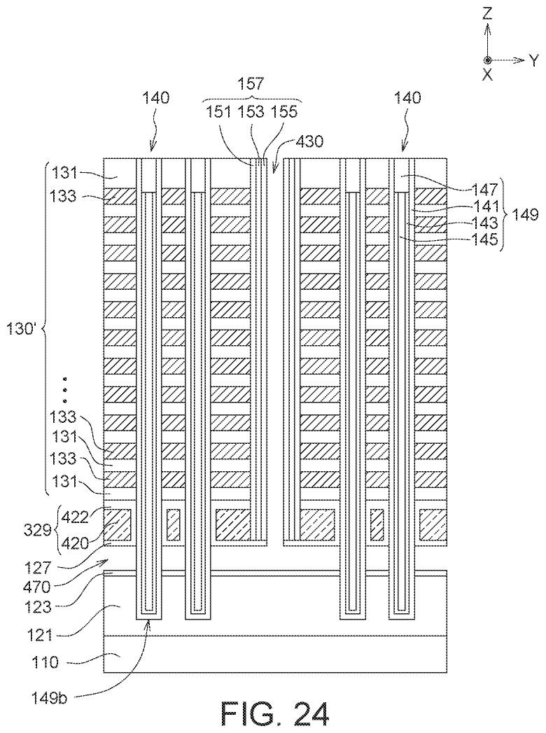

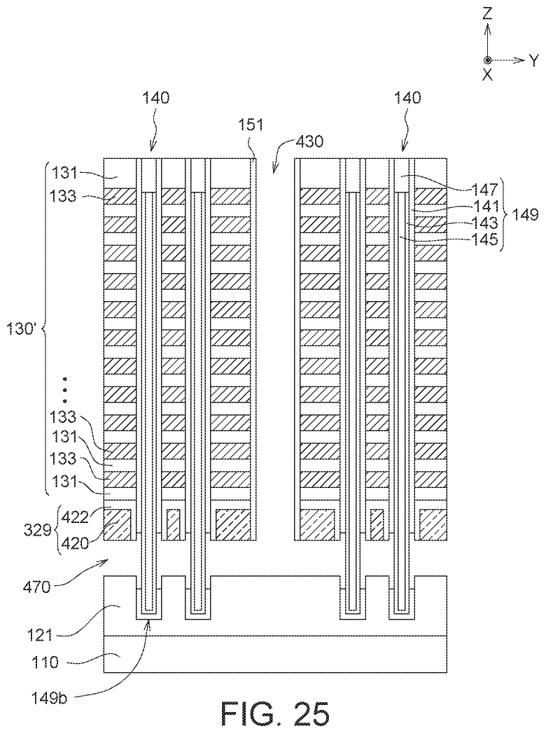

Please refer to FIG. 24. An etching step may be performed to remove the middle semiconductor material layer 125 through the trench 430 to form the slits 470. The slit 470 is disposed between the first interlayer insulating layer 123 and the second interlayer insulating layer 127. A portion of the sidewalls of channel structures 149 is exposed by the slit 470. Specifically, a portion of the sidewall of the memory film 141 of the channel structure 149 is exposed by the slit 470.

Please refer to FIG. 25. One or more etching steps may be performed to remove a portion of the memory film 141 of the channel structure 149, the first interlayer insulating layer 123, the second interlayer insulating layer 127, and portions of the insulating films (i.e., the insulating film 153 and insulating film 155). In one embodiment, the insulating film 151 disposed on the sidewalls of the trench 430 may be retained.

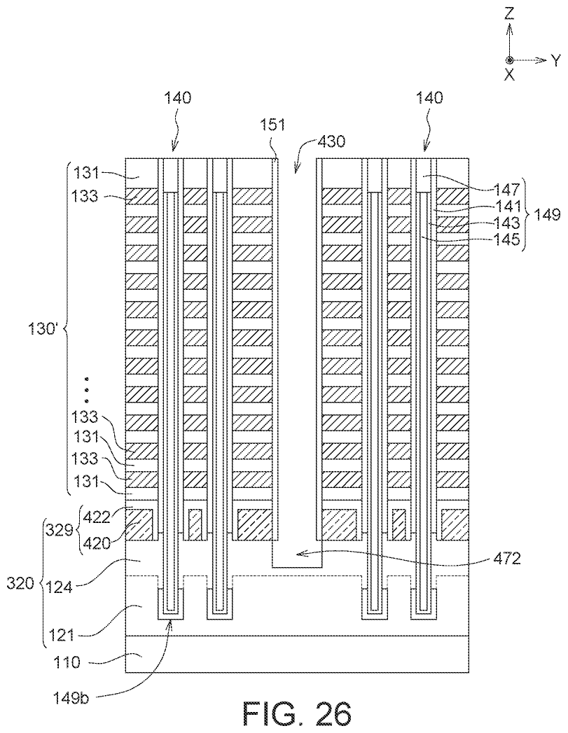

Please refer to FIG. 26. A refilled semiconductor material layer 124 may be formed between the lower semiconductor material layer 121 and the upper conductive layer 329 by a deposition process. For example, a semiconductor material may be deposited in the slit 470 by a deposition process, and then an etching back process is used to remove a portion of the refilled semiconductor material layer 124 to form an extending opening 472, which expose the refilled semiconductor material layer 124. The trench 430 and the extending opening 472 may communicate with each other. In one embodiment, the refilled semiconductor material layer 124 may connect or contact the memory film 141, the channel film 143, the lower semiconductor material layer 121 and the upper conductive layer 329. The lower semiconductor material layer 121, the refilled semiconductor material layer 124 and the upper conductive layer 329 may form the ground layer 320.

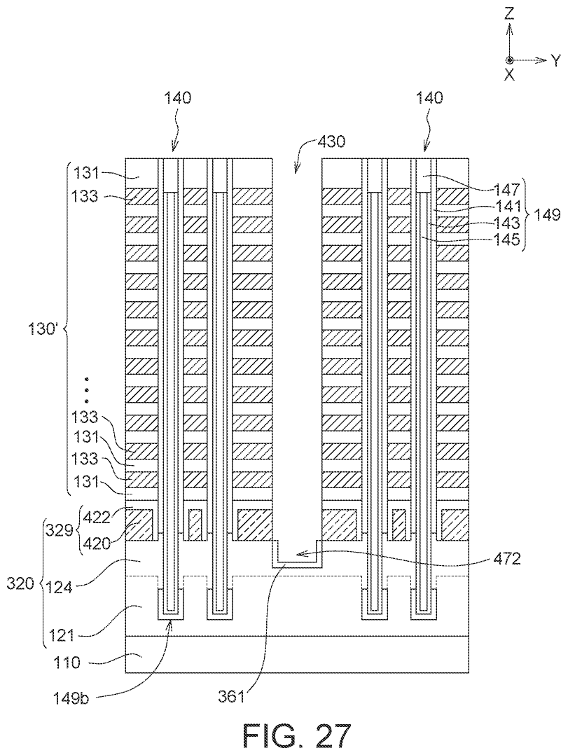

Please refer to FIG. 27. An etching step may be performed to remove the remaining portion of the insulating film 151 and a protective layer 361 is formed on the sidewalls and bottom of the extending opening 472. The protective layer 361 may cover the ground layer 320 exposed by the extending opening 472. In one embodiment, the protective layer 361 may include an insulating material, and the insulating material includes an oxide, such as silicon oxide. For example, the surface of the ground layer 320 exposed by the extending opening 472 can be oxidized to be the protective layer 361 by an oxidation process.

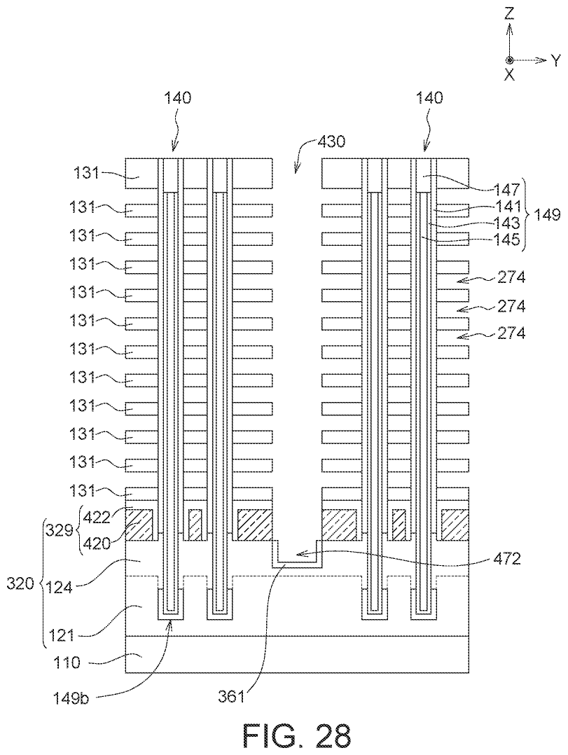

Please refer to FIG. 28. An etching step may be performed through the trench 430 to remove the sacrificial layers 133 of the laminated body 130′, and a plurality of spaces 274 between the insulating layers 131 are formed. In this etching step, the protective layer 361 may protect the ground layer 320 to prevent the ground layer 320 from being removed in the etching step. In one embodiment, the etching step may include wet etching, such as using hot phosphoric acid (H₃PO₄) or other suitable chemicals.

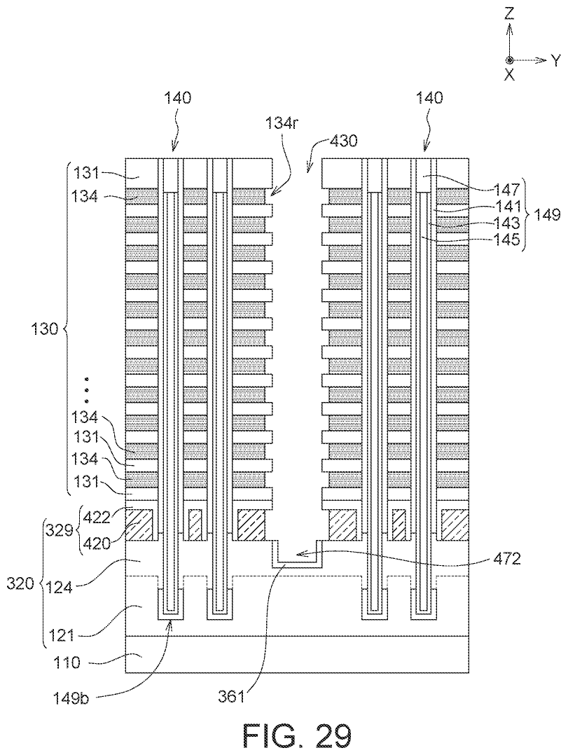

Please refer to FIG. 29. The plurality of spaces 274 are filled with a conductive material to form a plurality of conductive layers 134 disposed between the plurality of insulating layers 131. For example, a conductive material is deposited in the plurality of spaces 274, and then an etching back process is performed to remove a small portion of each of the conductive layers 134 adjacent to the trench 430, and a small portion of the conductive material layer 420 adjacent to the trench 430 is also removed, to form a plurality of recesses 134r disposed between the insulating layers 131 and the conductive layers 134 and between the insulating material layer 422 and the conductive material layer 420. The trench 430 and the recess 134r communicate with each other. The alternately stacked insulating layers 131 and the conductive layers 134 may jointly form the stacked structure 130.

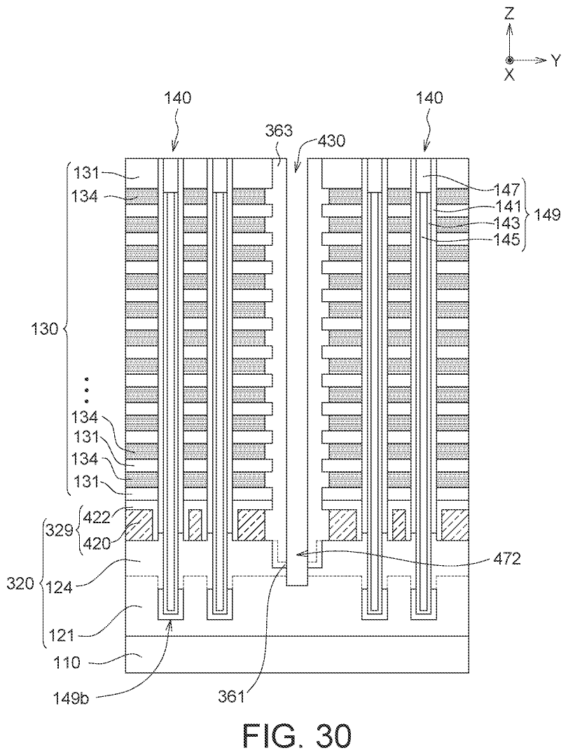

Please refer to FIG. 30. An isolation material layer 363 may be formed by a deposition process to be filled in the recesses 134r and lined in the trenches 430 and the extending opening 472. Thereafter, an etching step may be performed to remove a portion of the isolation material layer 363 and protective layer 361 at the bottom of the extending opening 472, and expose the ground layer 320. Thereby, the isolation material layer 363 covering the sidewalls of the trench 430 and the extending opening 472 can be formed. That is, the isolation material layer 363 may cover the exposed sidewalls of the conductive layers 131 and the insulating layers 134 of the stacked structure 130 and cover the protective layer 361. In one embodiment, the isolation material layer 363 may include an oxide, such as a low temperature oxide (LTO).

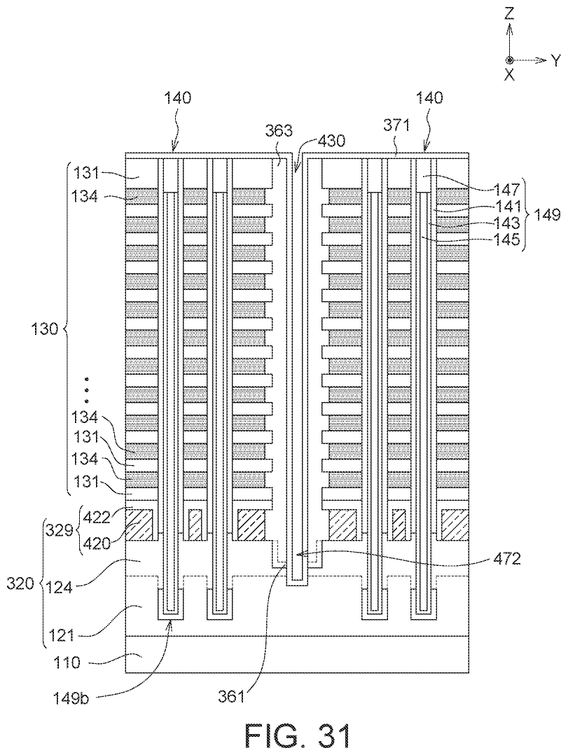

Please refer to FIG. 31. After the isolation material layer 363 is formed, a body barrier layer 371 may be lined on the stacked structure 130 and in the trench 430 and extending opening 472 by a deposition process. The body barrier layer 371 may directly contact the ground layer 320.

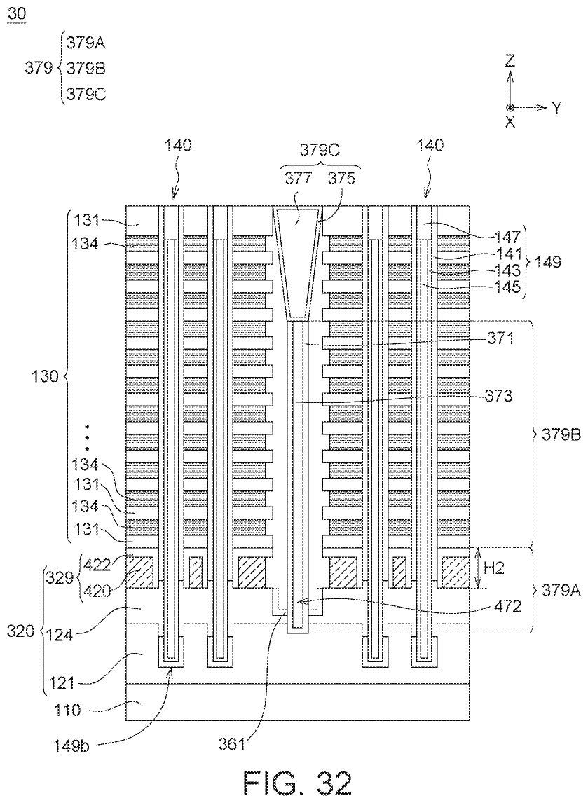

Please refer to FIG. 32. The excess portion of body barrier layer 371 on the stacked structure 130 can be removed, and the lower conductive layer 373 can be formed in the trench 430 and the extending opening 472, and then a portion of the isolation material layer 363, the body barrier layer 371 and the lower conductive layer 373 disposed in the upper portion of the trench 430 is removed, to form an upper opening (not shown), and a plug 379C including an upper barrier layer 375 and an upper conductor 377 is formed in the upper opening. The body barrier layer 371 and the lower conductive layer 373 disposed below the plug 379C form the middle body portion 379B and the bottom body portion 379A. That is, the middle body portion 379B and the bottom body portion 379A include the body barrier layer 371 and the lower conductive layer 373. In this way, a conductive pillar 379 including the bottom body portion 379A, the middle body portion 379B, and the plug 379C is formed.

In one embodiment, the material of the body barrier layer 371 and the upper barrier layer 375 can be independently titanium (Ti), titanium nitride (TiN), tantalum (Ta), tantalum nitride (TaN) or other suitable barrier material. In the present embodiment, the method for fabricating the conductive pillar 379 is the same as or similar to the method for fabricating the conductive pillars 179. It should be understood that the conductive pillars 379 can be applied to the embodiments described above or other embodiments.

As shown in FIG. 32, the semiconductor device 30 includes a circuit board 110, a ground layer 320, a stacked structure 130, a plurality of channel structures 149, an isolation material layer 363 and at least one conductive pillar 379. The ground layer 320 is disposed on the circuit board 110, and the stacked structure 130 is disposed on the ground layer 320.

The ground layer 320 includes a lower semiconductor material layer 121, a refilled semiconductor material layer 124 disposed on the lower semiconductor material layer 121, and an upper conductive layer 329 disposed on the refilled semiconductor material layer 121. The upper conductive layer 329 may be a composite layer, for example, the upper conductive layer 329 includes a conductive material layer 420 and an insulating material layer 422. The material of the conductive material layer 420 includes a metal material, such as tungsten.

The stacked structure 130 includes a plurality of insulating layers 131 and a plurality of conductive layers 134 alternately stacked on the ground layer 320 along the Z direction (e.g., the first direction). The channel structures 149 penetrate the stacked structure 130 along the Z direction (e.g., the first direction) and extend into the ground layer 320. More specifically, the ground layer 320 includes the lower semiconductors material layer 121, the refilled semiconductor material layer 124 and the upper conductive layer 329 sequentially stacked on the circuit board 110 along the Z direction, and the lower channel ends 149b of the channel structures 149 may extend into the lower semiconductor material layer 121. The conductive material layer 420 and the channel structures 149 are separated by an insulating material, and the conductive material layer 420 surrounds the channel structures 149.

According to an embodiment, in the Z direction (e.g., the first direction), a height H2 is formed between a bottom surface of the bottommost insulating layer 131 of the stacked structure 130 and a bottom surface of the upper conductive layer 329. The height H2 is greater than 0 nm and less than or equal to 60 nm (0 nm<H2≤60 nm), such as 20 to 60 nm, 25 to 55 nm or other suitable ranges. The height of the conductive material layer 420 in the first direction may be greater than the height of the insulating material layer 422 in the first direction.

Compared with the comparative example without the conductive material layer as the etch stop layer, in the semiconductor devices according to some embodiments of the present application, since the conductive material layer is formed as the etch stop layer, the etching process for forming the trench can be safely stopped at the conductive material layer, that is, the depth of the trench can be precisely controlled, and there is no problem of over-etching. Accordingly, in the subsequent process of forming the conductive pillar, the depth of the conductive pillar can be well controlled, and it is not easy to generate a seam disposed under the conductive pillar, which can prevent the conductive material from passing through the seam to cause a short circuit between the conductive pillar and the channel structures. Therefore, the formed semiconductor device of the present application may have better electrical properties.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a ground layer comprising a lower semiconductor material layer, a refilled semiconductor material layer disposed on the lower semiconductor material layer, and an upper conductive layer disposed on the refilled semiconductor material layer;
a stacked structure disposed on the ground layer, and the stacked structure comprising a plurality of insulating layers and a plurality of conductive layers alternately stacked along a first direction; and
at least one conductive pillar penetrating the stacked structure along the first direction and extending into the ground layer, wherein the at least one conductive pillar comprises a bottom body portion, a middle body portion and a plug connected to each other, wherein the bottom body portion corresponds to the ground layer, and the middle body portion corresponds to middle and bottom portions of the stacked structure;
wherein, in a second direction different from the first direction, a portion of the bottom body portion overlapping the upper conductive layer has a first dimension, and a portion of the middle body portion overlapping a bottommost insulating layer of the stacked structure has a second dimension, and the first dimension is greater than the second dimension.

2. The semiconductor device according to claim 1, wherein, in the second direction, a portion of the middle body portion overlapping a portion disposed above the bottommost insulating layer of the stacked structure has a third dimension, the first dimension is greater than the third dimension, and the third dimension is greater than the second dimension.

3. The semiconductor device according to claim 1, further comprising an isolation material layer disposed between the conductive pillar and the stacked structure and between the conductive pillar and the ground layer, wherein in the second direction, a maximum dimension of a portion of the isolation material layer overlapping the upper conductive layer is greater than a maximum dimension of a portion of the isolation material layer overlapping the stacked structure.

4. The semiconductor device according to claim 1, wherein the middle body portion and the bottom body portion comprise a body barrier layer and a lower conductive layer, and the plug comprises an upper barrier layer and an upper conductor, and a material of the lower conductive layer is different from a material of the upper conductor.

5. The semiconductor device according to claim 1, wherein an outer sidewall of the conductive pillar has a kink profile at a portion adjacent to the bottommost insulating layer of the stacked structure.

6. The semiconductor device according to claim 1, further comprising a circuit board, and the ground layer is disposed on the circuit board.

7. The semiconductor device according to claim 1, further comprising a plurality of channel structures, wherein the channel structures penetrate through the stacked structure along the first direction and extend into the ground layer.

8. The semiconductor device according to claim 1, wherein in the first direction, a height is formed between a bottom surface of the bottommost insulating layer of the stacked structure and a bottom surface of the upper conductive layer, and the height is greater than 0 nm, and is less than or equal to 60 nm.

9. The semiconductor device according to claim 1, wherein in the second direction, a portion of the bottom body portion overlapping a top protrusion of the refilled semiconductor material layer has the first dimension.

10. A semiconductor device, comprising:
a ground layer comprising a lower semiconductor material layer, a refilled semiconductor material layer disposed on the lower semiconductor material layer, and an upper conductive layer disposed on the refilled semiconductor material layer; and
a stacked structure disposed on the ground layer, and the stacked structure comprising a plurality of insulating layers and a plurality of conductive layers alternately stacked along a first direction;
wherein the upper conductive layer comprises a conductive material layer, and a material of the conductive material layer comprises a metal material.

11. A method for fabricating a semiconductor device, comprising:
providing a multilayer structure on a circuit board, the multilayer structure comprising a lower semiconductor material layer, a first interlayer insulating layer, a middle semiconductor material layer, a second interlayer insulating layer and an upper conductive layer sequentially stacked on the circuit board along a first direction;
forming a conductive material layer in the upper conductive layer, wherein the conductive material layer includes a metal material;
forming a laminated body on the upper conductive layer, the laminated body comprising a plurality of insulating layers and a plurality of sacrificial layers stacked alternately; and
forming at least one trench in the laminated body, wherein the at least one trench extends along the first direction, penetrates through the laminated body and stops at the conductive material layer.

12. The method according to claim 11, further comprising:
removing a portion of the upper conductive layer to form a groove exposing the second interlayer insulating layer; and
filling a conductive material in the groove to form the conductive material layer.

13. The method according to claim 12, further comprising:
forming a plurality of vertical openings in the laminated body, wherein the vertical openings penetrate through the laminated body, the upper conductive layer, the second interlayer insulating layer, the middle semiconductor material layer and the first interlayer insulating layer along the first direction, and stop at the lower semiconductor material layer;
sequentially depositing a memory film, a channel film, an insulating pillar and a pad in each of the vertical openings to form a plurality of channel structures; and
removing the conductive material layer and exposing the groove.

14. The method according to claim 12, wherein in a second direction different from the first direction, a width of the groove is greater than a width of the trench.

15. The method according to claim 13, further comprising:
forming a spacer structure on a sidewall of the trench and a sidewall of the groove, and the spacer structure comprising a plurality of insulating films;
forming a notch penetrating through the second interlayer insulating layer and exposing the middle semiconductor material layer;
removing the middle semiconductor material layer through the trench, the groove and the notch to form a slit;
removing a portion of the memory film, the first interlayer insulating layer, the second interlayer insulating layer, and a portion of the insulating films;
forming a refilled semiconductor material layer between the lower semiconductor material layer and the upper conductive layer;
removing a portion of the refilled semiconductor material layer to form an extending opening; and
removing a remaining portion of the insulating films, and forming a protective layer on sidewalls of the groove, the extending opening and on a bottom of the extending opening.

16. The method according to claim 15, further comprising:
removing the sacrificial layers of the laminated body through the trench to form spaces between the insulating layers;
filling the spaces with a conductive material to form a plurality of conductive layers between the insulating layers, and forming a stacked structure comprising the insulating layers and the conductive layers alternately stacked along the first direction;
forming a plurality of recesses between the insulating layers and the conductive layers;
forming an isolation material layer in the recesses, the trench, the groove and the extending opening;
removing a portion of the isolation material layer and the protective layer at a bottom of the extending opening and exposing the ground layer; and
forming a conductive pillar between the isolation material layer and the ground layer.

17. The method according to claim 16, wherein the method for forming the conductive pillar further comprises:
forming a body barrier layer lining on the stacked structure and in the trench, the groove and the extending opening;
removing an excess portion of the body barrier layer on the stacked structure;
forming a lower conductive layer in the trench, the groove and the extending opening; and
removing a portion of the isolation material layer, the body barrier layer, and the lower conductive layer disposed in an upper portion of the trench to form an upper opening, and forming a plug in the upper opening.

18. The method according to claim 17, wherein the portion of the memory film which is removed comprises a top removal portion, and the at least one conductive pillar comprises a bottom body portion, a middle body portion and a plug connected to each other, wherein
the bottom body portion corresponding to the top removal portion has a first dimension, a portion of the middle body portion overlapping a bottommost insulating layer of the stacked structure has a second dimension in a second direction different from the first direction, and the first dimension is greater than the second dimension.

19. The method according to claim 11, further comprising:
removing a portion of the upper conductive layer to form a plurality of holes exposing the second interlayer insulating layer; and
filling an insulating material in the holes.

20. The method according to claim 11, further comprising:
forming a plurality of vertical openings in the laminated body, wherein the vertical openings penetrate through the laminated body, the upper conductive layer, the second interlayer insulating layer, the middle semiconductor material layer and the first interlayer insulating layer along the first direction, and stop at the lower semiconductor material layer; and
sequentially depositing a memory film, a channel film, an insulating pillar and a pad in each of the vertical openings to form a plurality of channel structures,
wherein the conductive material layer surrounds the channel structures.
